(19) United States
(12) Patent Application Publication
(10) Pub. No.: US 2025/0089423 A1
(43) Pub. Date: Mar. 13, 2025

(54) DISPLAY DEVICE

(71) Applicant: LG Display Co., Ltd., Seoul (KR)

(72) Inventors: ByungHyun LEE, Paju-si (KR); Daeyoung SEO, Seoul (KR); MinSeok KIM, Seoul (KR); TaeYong KIM, Anyang-si (KR); Sumin LEE, Seoul (KR)

(21) Appl. No.: 18/767,047

(22) Filed: Jul. 9, 2024

(30) Foreign Application Priority Data
Sep. 13, 2023 (KR) 10-2023-0121472

(51) Int. Cl. H01L 33/62; H01L 25/075; H01L 25/16; H01L 27/12; H01L 33/40

(52) U.S. Cl. CPC H10H 20/857; H01L 25/0753; H01L 25/167; H10D 86/443; H10D 86/60; H10H 20/835

(57) ABSTRACT

According to an aspect of the present disclosure, a display device includes a substrate configured to define a plurality of pixel areas, and a plurality of transmissive areas disposed between the plurality of pixel areas; a plurality of pixels disposed in the plurality of pixel areas and each including a plurality of sub pixels; light-emitting elements respectively disposed in the plurality of sub pixels and each including a first electrode; and a repair line disposed between a pair of adjacent sub pixels among the plurality of sub pixels, in which the light-emitting elements of the pair of sub pixels are disposed so that the first electrodes are directed toward the repair line. Therefore, the repair line may be formed to repair the plurality of sub pixels when the plurality of sub pixels is defective, thereby improving the yield of the display device.

### CROSS-REFERENCE TO RELATED APPLICATIONS

This application claims the priority of Korean Patent Application No. 10-2023-0121472 filed on Sep. 13, 2023, in the Korean Intellectual Property Office, the disclosure of which is incorporated herein by reference.

### TECHNICAL FIELD

The present disclosure relates to a transparent display device, and more particularly, to a transparent display device using a light emitting diode (LED).

### DESCRIPTION OF THE RELATED ART

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### BRIEF SUMMARY

The present disclosure provides a transparent display device having a high transmittance rate.

The present disclosure provides a display device in which an opaque line and a plurality of pixels are formed to overlap one another, thereby increasing an area of a transmissive area.

Still another object to be achieved by the present disclosure is to provide a display device in which a repair line for repairing a plurality of sub pixels, thereby improving a yield.

Yet another object to be achieved by the present disclosure is to provide a display device in which a repair line is configured as a single-layer structure made of a transparent conductive material, thereby simplifying the structure of the repair line.

Still yet another object to be achieved by the present disclosure is to provide a display device in which a repair line is made of only a transparent conductive material, thereby minimizing a decrease in transmittance rate of a transmissive area.

A further object to be achieved by the present disclosure is to provide a display device in which light-emitting elements are disposed to be symmetric, such that a plurality of repair lines is disposed so as not to overlap one another.

Another further object to be achieved by the present disclosure is to provide a display device in which light-emitting elements of a pair of adjacent sub pixels are disposed to be symmetric, such that a plurality of repair lines may be disposed within a shortest straight distance.

Still another further object to be achieved by the present disclosure is to provide a display device in which a repair line, which connects two light-emitting elements, has a shortest length, such that resistance of the repair line may be improved, and the display device may operate with low power consumption.

Yet another further object to be achieved by the present disclosure is to provide a display device in which a plurality of red light-emitting elements, a plurality of green light-emitting elements, and a plurality of blue light-emitting elements may be disposed at uniform intervals.

Objects of the present disclosure are not limited to the above-mentioned objects, and other objects, which are not mentioned above, can be clearly understood by those skilled in the art from the following descriptions.

According to an aspect of the present disclosure, a display device includes a substrate configured to define a plurality of pixel areas disposed to be spaced apart from one another, and a plurality of transmissive areas disposed between the plurality of pixel areas; a plurality of pixels disposed in the plurality of pixel areas and each including a plurality of sub pixels; light-emitting elements respectively disposed in the plurality of sub pixels and each including a first electrode; and a repair line disposed between a pair of adjacent sub pixels among the plurality of sub pixels, in which the light-emitting elements of the pair of sub pixels are disposed so that the first electrodes are directed toward the repair line. Therefore, the repair line may be formed to repair the plurality of sub pixels when the plurality of sub pixels is defective, thereby improving the yield of the display device.

Other detailed matters of the example embodiments are included in the detailed description and the drawings.

According to the present disclosure, it is possible to implement the transparent display device with the improved transmittance rate.

According to the present disclosure, the opaque components may be disposed to overlap one another, among the components of the display device, thereby resulting in the increased area of the transmissive area of the display device.

According to the present disclosure, the opaque line and the plurality of pixels may be formed to overlap one another, thereby increasing an area of the transmissive area.

According to the present disclosure, the repair line may be formed to repair the plurality of sub pixels, thereby improving the yield of the display device.

According to the present disclosure, the repair line may be made of a transparent conductive material, thereby simplifying the structure of the repair line.

According to the present disclosure, the repair line may be made of only a transparent conductive material, thereby minimizing the decrease in transmittance rate of the transmissive area.

According to the present disclosure, the plurality of repair lines is disposed so as not to overlap one another, such that the plurality of repair lines may be formed as a single layer on the same layer.

According to the present disclosure, the light-emitting elements of the pair of sub pixels, which are connected to each other during the repair process, are disposed to be symmetric, such that the plurality of repair lines may be formed within the shortest straight distance between the two light-emitting elements.

According to the present disclosure, the repair line, which connects the two light-emitting elements, has the shortest straight length, such that the line resistance may be reduced, and the display device may operate with low power consumption.

According to the present disclosure, the plurality of red light-emitting elements, the plurality of green light-emitting elements, and the plurality of blue light-emitting elements may be disposed at uniform intervals, thereby improving the image quality.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present disclosure;

FIG. 2A is a partial cross-sectional view of the display device according to embodiments of the present disclosure;

FIG. 2B is a perspective view of a tiling display device according to embodiments of the present disclosure;

FIG. 3 is a schematic enlarged top plan view of a display area of the display device according to embodiments of the present disclosure;

FIG. 4 is an enlarged top plan view of the display device according to embodiments of the present disclosure;

FIGS. 5A and 5B are cross-sectional views of sub pixels of the display device according to embodiments of the present disclosure; and

FIG. 6 is a cross-sectional view of the sub pixel of the display device according to embodiments of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and embodiments can be carried out independently of or in association with each other.

Hereinafter, an example embodiments of the present disclosure will be described in detail with reference to accompanying drawings.

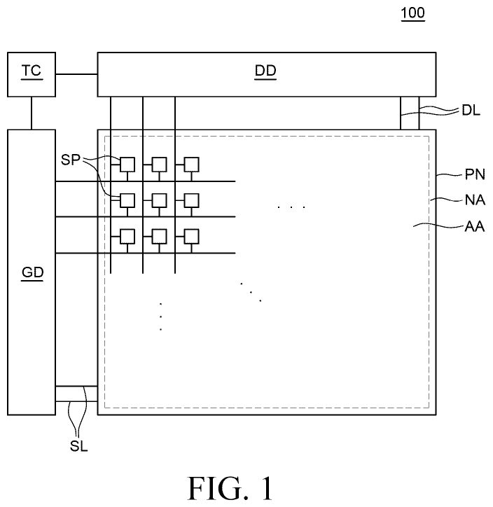

FIG. 1 is a schematic configuration view of a display device according to an embodiment of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub pixels SP, the gate drive part GD configured to supply various types of signals to the display panel PN, and the timing controller TC configured to control the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD supplies data voltages to a plurality of data lines DL in response to a plurality of data control signals and image data provided from the timing controller TC. The data drive part DD may convert image data into data voltages by using a reference gamma voltage and supply the converted data voltages to the plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of sub pixels SP. In the display panel PN, the plurality of scan lines SL and the plurality of data lines DL may intersect one another, and the plurality of sub pixels SP may be formed at intersection points between the scan line SL and the data line DL.

A display area AA and a non-display area NA may be defined on the display panel PN.

The display area AA is an area of the display device 100 in which images are displayed. The display area AA may include the plurality of sub pixels SP constituting a plurality of pixels PX, and a pixel circuit configured to operate the plurality of sub pixels SP. The plurality of sub pixels SP is minimum units that constitute the display area AA. The n sub pixels SP may constitute a single pixel PX. Thin-film transistors and the like for operating a plurality of light-emitting elements 120 may be respectively disposed in the plurality of sub pixels SP. The plurality of light emitting elements 120 may be differently defined depending on the type of display panel PN. For example, in case that the display panel PN is an inorganic light-emitting display panel, the light-emitting element 120 may be a light-emitting diode (LED) or a micro light-emitting diode (micro LED).

A plurality of signal lines for transmitting various types of signals to the plurality of sub pixels SP is disposed in the display area AA. For example, the plurality of signal lines may include the plurality of data lines DL for supplying data voltages to the plurality of sub pixels SP, and the plurality of scan lines SL for supplying scan signals to the plurality of sub pixels SP. The plurality of scan lines SL may extend in one direction in the display area AA and be connected to the plurality of sub pixels SP. The plurality of data lines DL may extend in a direction different from one direction in the display area AA and be connected to the plurality of sub pixels SP. In addition, a low-potential power line VSS, a high-potential power line VDD, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the sub pixels SP in the display area AA. Alternatively, the non-display area NA may include drive ICs such as gate drivers IC and data drivers IC.

Meanwhile, the non-display area NA may be positioned on a rear surface of the display panel PN, i.e., a surface on which the sub pixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub pixels SP by a gate-in-active area (GIA) method in the display area AA.

For example, the data drive part DD and the timing controller TC may be formed on a separate flexible film and a printed circuit board and electrically connect the display panel PN, the data drive part DD, and the timing controller TC by a method of bonding the flexible film and the printed circuit board to a pad electrode formed in the non-display area NA of the display panel PN.

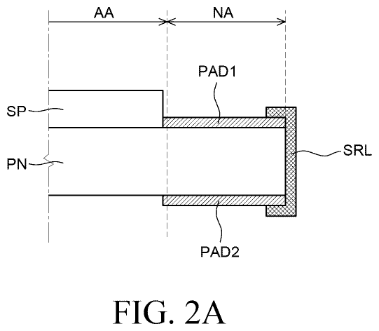

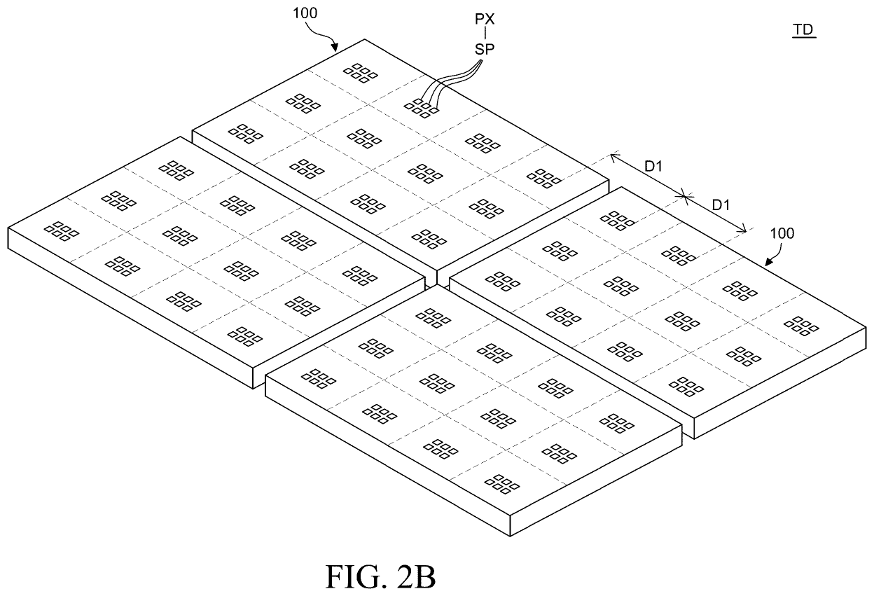

As another example, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. Therefore, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to embodiments of the present disclosure. FIG. 2B is a perspective view of a tiling display device according to embodiments of the present disclosure.

A plurality of pad electrodes for transmitting various types of signals to the plurality of sub pixels SP is disposed in the non-display area NA of the display panel PN. For example, a first pad electrode PAD1 configured to transmit signals to the plurality of sub pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub pixels SP may extend from the display area AA to the non-display area NA and be electrically connected to the first pad electrode PAD1.

Further, the side line SRL is disposed on a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub pixels SP through the second pad electrode PAD2, the side line SRL, and the first pad electrode PAD1. Therefore, the drive component is disposed on the rear surface of the display panel PN, and a signal transmission route is defined between the front and rear surfaces of the display panel PN, which may minimize an area of the non-display area NA on the front surface of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the minimized bezel, a seam area in which no image is displayed between the display devices 100 may be minimized, thereby improving display quality.

For example, the plurality of sub pixels SP may constitute a single pixel PX. An interval D1 between an outermost peripheral pixel PX of one display device 100 and an outermost peripheral pixel PX of another display device 100 adjacent to one display device 100 may be implemented to be equal to the interval D1 between the pixels PX in one display device 100. Therefore, the seam area may be minimized as a constant interval of the pixels PX is implemented between the display device 100 and the display device 100.

However, as illustrated in FIG. 2A and FIG. 2B, the display device 100 according to embodiments of the present disclosure may be a general display device in which the bezel is present. However, the present disclosure is not limited thereto.

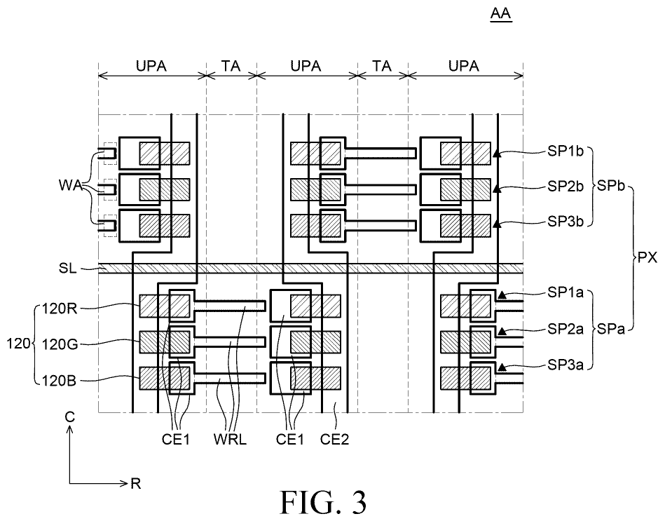

Hereinafter, the display panel PN of the display device 100 according to embodiments of the present disclosure will be further described with reference to FIGS. 3 to 6.

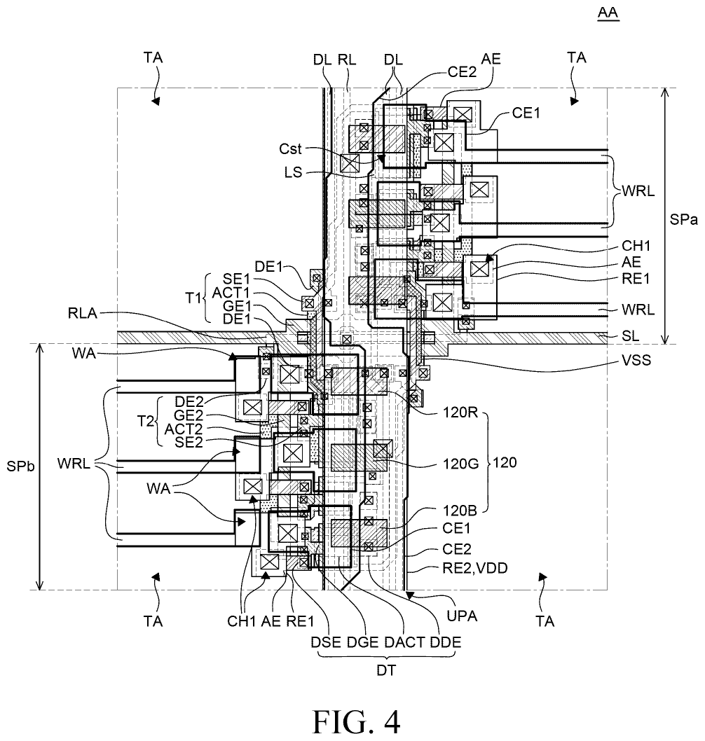

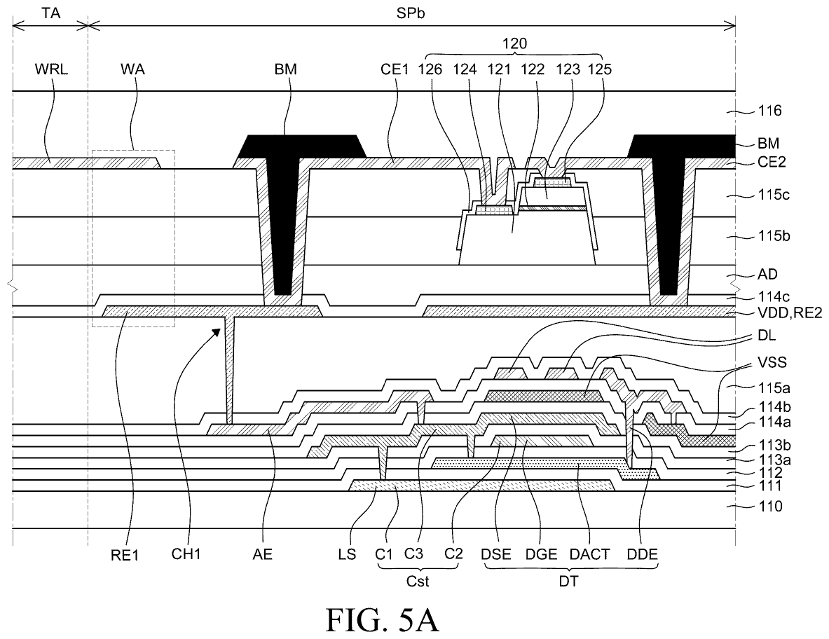

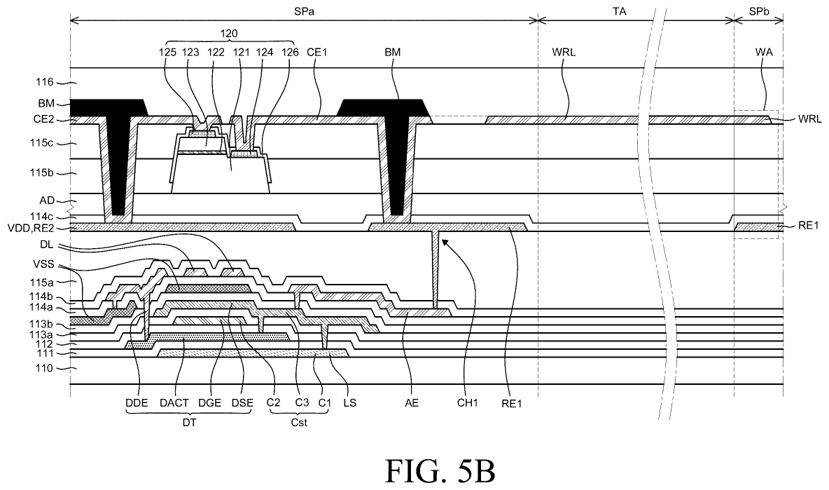

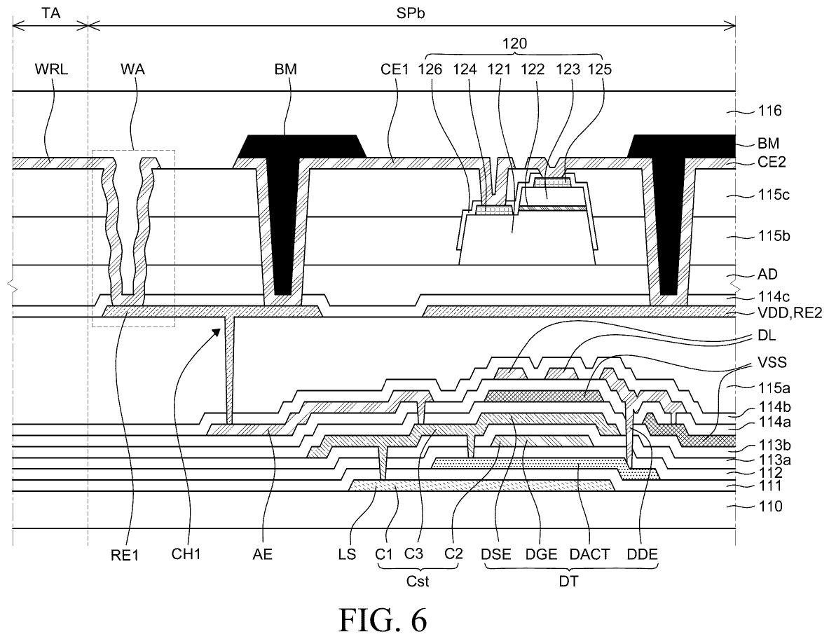

FIG. 3 is a schematic enlarged top plan view of the display area of the display device according to embodiments of the present disclosure. FIG. 4 is an enlarged top plan view of the display device according to embodiments of the present disclosure. FIGS. 5A and 5B are cross-sectional views of the sub pixels of the display device according to embodiments of the present disclosure. FIG. 6 is a cross-sectional view of the sub pixel of the display device according to embodiments of the present disclosure. For example, FIG. 4 is an enlarged top plan view of one pixel PX, FIG. 5A is a cross-sectional view of a B-type sub pixel SPb, and FIG. 5B is a cross-sectional view of an A-type sub pixel SPa. FIG. 6 is a cross-sectional view of the B-type sub pixel SPb after the repair process is completed. For convenience of description, FIG. 3 illustrates only the plurality of light-emitting elements 120, a plurality of repair lines WRL, a plurality of first connection electrodes CE1, a second connection electrode CE2, and the scan line SL. Further, in FIG. 4, the first connection electrode CE1 and the second connection electrode CE2 are indicated by thick solid lines, and the hatching thereof is omitted. The hatching of a first reflective electrode RE1 and a second reflective electrode RE2 is omitted.

With reference to FIG. 3, the display area AA includes a plurality of pixel areas UPA and a plurality of transmissive areas TA.

The plurality of pixel areas UPA is formed in the display area AA. The plurality of pixel areas UPA are areas in which the pixels PX are disposed and images are displayed. The plurality of pixel areas UPA may be disposed to be spaced apart from one another, e.g., in the row direction R, with the plurality of transmissive areas TA interposed therebetween. For example, the plurality of pixel areas UPA may be disposed in a plurality of rows and a plurality of columns.

The plurality of sub pixels SP, which constitutes the pixel PX, are disposed in each of the plurality of pixel areas UPA. The plurality of sub pixels SP may each include the light-emitting element 120 and the pixel circuit and independently emit light. For example, the plurality of sub pixels SP may include first sub pixels SP1a and SP1b, second sub pixels SP2a and SP2b, and third sub pixels SP3a and SP3b that emit light beams with different colors. For example, the first sub pixels SP1a and SP1b may be red sub pixels, the second sub pixels SP2a and SP2b may be green sub pixels, and the third sub pixels SP3a and SP3b may be blue sub pixels. However, the present disclosure is not limited thereto. In the present disclosure, the configuration is described in which the plurality of sub pixels SP includes three sub pixels SP. However, the plurality of sub pixels SP may include four or more sub pixels SP further including sub pixels SP that display additional colors including white.

Hereinafter, the description will be made on the assumption that one pixel PX includes the two first sub pixels SP1a and SP1b, the two second sub pixels SP2a and SP2b, and the two third sub pixels SP3a and SP3b, i.e., two red sub pixels, two green sub pixels, and two blue sub pixels. However, the configuration of the pixel PX is not limited thereto.

The plurality of sub pixels SP, which constitutes one pixel PX, is disposed in a line in a column direction C. The plurality of sub pixels SP may be disposed in the column direction and overlap a line extending in the column direction. For example, the plurality of sub pixels SP may overlap the data line DL, a reference line RL, the high-potential power line VDD, the low-potential power line VSS, and the like extending in the column direction C. The pixel area UPA may be formed in an area in which a plurality of opaque lines is disposed, such that an area of the transmissive area TA may be ensured in the entire display area AA. The pixel area UPA, in which the plurality of sub pixels SP is disposed, may be an area that has a low transmittance rate and is substantially opaque because of the configurations of the pixel circuits, the light-emitting elements 120, and the like disposed in the plurality of sub pixels SP. Therefore, the plurality of sub pixels SP in the pixel area UPA may be disposed to overlap the opaque lines extending in the column direction, e.g., the data line DL, the reference line RL, the low-potential power line VSS, and the high-potential power line VDD. Therefore, the plurality of sub pixels SP in the pixel area UPA is disposed to overlap the plurality of lines, such that an area of the opaque area may be reduced in the entire display area AA, and an increased area of the transmissive area TA may be formed.

Further, the plurality of sub pixels SP included in one pixel PX may be disposed in both the areas at the two opposite sides of the scan line SL. For example, in the area at one side of the scan line SL, one of the pair of first sub pixels SP1a and SP1b, one of the pair of second sub pixels SP2a and SP2b, and one of the pair of third sub pixels SP3a and SP3b may be sequentially disposed in the column direction. Further, in the area at the other side of the scan line SL, the remainder of the pair of first sub pixels SP1a and SP1b, the remainder of the pair of second sub pixels SP2a and SP2b, and the remainder of the pair of third sub pixels SP3a and SP3b may be sequentially disposed in the column direction. Therefore, the plurality of sub pixels SP, which constitutes one pixel PX, may be disposed in the column direction in the order of the first sub pixel SP1b, the second sub pixel SP2b, the third sub pixel SP3b, the first sub pixel SP1a, the second sub pixel SP2a, and the third sub pixel SP3a. However, the arrangement order of the plurality of sub pixels SP may be variously changed. However, the present disclosure is not limited thereto.

Meanwhile, the light-emitting element 120 of each of the plurality of sub pixels SP may be connected to the first connection electrode CE1 and the second connection electrode CE2 and operate. The first connection electrode CE1 is an electrode configured to electrically connect the light-emitting element 120 and a driving transistor DT, and the second connection electrode CE2 is an electrode configured to electrically connect the light-emitting element 120 and the high-potential power line VDD. In this case, the repair line WRL may be connected to some first connection electrodes CE1 among the plurality of first connection electrodes CE1. The repair line WRL may be connected only to the first connection electrodes CE1 of some of the sub pixels SP. When a defect occurs later, the repair line WRL may be electrically connected to any one of the remaining first connection electrodes CE1 to which the repair line WRL is not connected, such that the defective sub pixel SP may be repaired.

Meanwhile, in the present disclosure, the configuration has been described in which the light-emitting element 120 is electrically connected to the high-potential power line VDD, and the driving transistor DT is connected to the low-potential power line VSS. However, in accordance with the pixel structure, the light-emitting element 120 may be connected to the low-potential power line VSS, and the driving transistor DT may be connected to the high-potential power line VDD. However, the present disclosure is not limited thereto. Further, in case that the light-emitting element 120 is connected to the low-potential power line VSS and the driving transistor DT is connected to the high-potential power line VDD, the first connection electrode CE1 may be connected to the light-emitting element 120 and the low-potential power line VSS, and the second connection electrode CE2 may be connected to the driving transistor DT and the light-emitting element 120. On the contrary, the first connection electrode CE1 may be connected to the light-emitting element 120 and the driving transistor DT, and the second connection electrode CE2 may be connected to the light-emitting element 120 and the low-potential power line VSS.

Hereinafter, for convenience of description, among the plurality of sub pixels SP, the sub pixel SP, in which the first connection electrode CE1 is connected to the repair line WRL, will be referred to as the A-type sub pixel SPa and described, and the sub pixel SP, in which the first connection electrode CE1 is not connected to the repair line WRL, will be referred to as the B-type sub pixel SPb and described. In some embodiments, a repair line WRL is connected to a first connection electrode CE1 of an A-type sub-pixel, extends through the adjacent transmission area TA, and extends into a pixel area UPA of an adjacent B-type sub-pixel, without contacting the adjacent B-type sub-pixel.

Some of the plurality of sub pixels SP disposed in one pixel area UPA may be the A-type sub pixels SPa, and the remaining sub pixels SP may be the B-type sub pixels SPb. One of the pair of first sub pixels SP1a and SP1b, one of the pair of second sub pixels SP2a and SP2b, and one of the pair of third sub pixels SP3a and SP3b may be the A-type sub pixels SPa. The remainder of the pair of first sub pixels SP1a and SP1b, the remainder of the pair of second sub pixels SP2a and SP2b, and the remainder of the pair of third sub pixels SP3a and SP3b may be the B-type sub pixels SPb. For example, the pixel PX disposed in one pixel area UPA may include a first A-type sub pixel SP1a, a first B-type sub pixel SP1b, a second A-type sub pixel SP2a, a second B-type sub pixel SP2b, a third A-type sub pixel SP3a, and a third B-type sub pixel SP3b.

In each of the pixel areas UPA of some of the plurality of pixel areas UPA, the A-type sub pixel SPa may be disposed in the area at a first side of the scan line SL, and the B-type sub pixel SPb may be disposed in the area at a second side of the scan line SL, opposite to the first side. For example, in some of the pixel areas UPA, the sub pixels SP may be disposed in the column direction in the order of the first A-type sub pixel SP1a, the second A-type sub pixel SP2a, the third A-type sub pixel SP3a, the first B-type sub pixel SP1b, the second B-type sub pixel SP2b, and the third B-type sub pixel SP3b.

In the remaining pixel areas UPA among the plurality of pixel areas UPA, the B-type sub pixel SPb may be disposed in the area at one side of the scan line SL, and the A-type sub pixel SPa may be disposed in the area at the other side of the scan line SL. In the remaining pixel areas UPA, the sub pixels SP may be disposed in the column direction in the order of the first B-type sub pixel SP1b, the second B-type sub pixel SP2b, the third B-type sub pixel SP3b, the first A-type sub pixel SP1a, the second A-type sub pixel SP2a, and the third A-type sub pixel SP3a.

Therefore, in the pixel area UPA disposed in an n-th column, the A-type sub pixel SPa may be disposed in the area at one side of the scan line SL. In the pixel area UPA disposed in an (n+1)th column, the A-type sub pixel SPa may be disposed in the area at the other side of the scan line SL.

Further, some of the pixel areas UPA, in which the A-type sub pixel SPa is disposed in the area at one side of the scan line SL, and the remaining pixel areas UPA, in which the A-type sub pixel SPa is disposed in the area at the other side of the scan line SL, may be disposed in different columns. In this case, the A-type sub pixels SPa and the B-type sub pixels SPb may be alternately disposed in a row direction. For example, the first A-type sub pixels SP1a and the first B-type sub pixels SP1b may be alternately disposed in the same row. The second A-type sub pixels SP2a and the second B-type sub pixels SP2b may be alternately disposed in the same row. The third A-type sub pixels SP3a and the third B-type sub pixels SP3b may be alternately disposed in the same row.

In addition, a group of the plurality of A-type sub pixels SPa and a group of the plurality of B-type sub pixels SPb may also be alternately disposed in the column direction. For example, a group of the A-type sub pixels SPa including the first A-type sub pixel SP1a, the second A-type sub pixel SP2a, and the third A-type sub pixel SP3a and a group of the B-type sub pixels SPb including the first B-type sub pixel SP1b, the second B-type sub pixel SP2b, and the third B-type sub pixel SP3b may be alternately disposed in the column direction.

The repair line WRL and the A-type sub pixel SPa may be used to repair the B-type sub pixel SPb, and the repair line WRL and the B-type sub pixel SPb may be used to repair the A-type sub pixel SPa. When a circuit defect occurs on the A-type sub pixel SPa, the repair line WRL may be used to connect the light-emitting element 120 of the A-type sub pixel SPa to the circuit of the B-type sub pixel SPb and operate the light-emitting element 120. On the contrary, when a circuit defect occurs on the B-type sub pixel SPb, the repair line WRL may be used to connect the light-emitting element 120 of the B-type sub pixel SPb to the circuit of the A-type sub pixel SPa and operate the light-emitting element 120.

Therefore, in the case of the sub pixel SP in which all the plurality of A-type sub pixels SPa and the plurality of B-type sub pixels SPb operate when the display device 100 operates, the display quality may deteriorate when a defect occurs on any one of the plurality of sub pixels SP. However, in the display device 100 according to embodiments of the present disclosure, even though a defect occurs on any one of the plurality of sub pixels SP, the light-emitting element 120 of the defective sub pixel SP is connected to the driving transistor DT of the A-type sub pixel SPa or the B-type sub pixel SPb adjacent to the defective sub pixel SP, such that the defective sub pixel SP may appear to operate normally.

As another example, when the display device 100 operates, one of the plurality of A-type sub pixels SPa or one of the plurality of B-type sub pixels SPb may be implemented as a main sub pixel that operates substantially, and the remaining A-type sub pixels SPa or the remaining B-type sub pixels SPb may be implemented as redundancy sub pixels for repairing the defective main sub pixel. A pixel circuit is formed in the redundancy sub pixel. Even though a defect occurs on the pixel circuit of the main sub pixel, the pixel circuit of the redundancy sub pixel may be connected to the light-emitting element of the main sub pixel and normally operate the light-emitting element of the main sub pixel.

Next, the light-emitting element 120 of the A-type sub pixel SPa and the light-emitting element 120 of the B-type sub pixel SPb may be disposed to be symmetric with respect to the repair line WRL. The repair line WRL is disposed between the first connection electrode CE1 of the A-type sub pixel SPa and the first connection electrode CE1 of the B-type sub pixel SPb. Therefore, the A-type sub pixel SPa and the B-type sub pixel SPb, which are disposed in columns adjacent to each other, may be formed such that the first connection electrodes CE1 face each other. The first connection electrode CE1 of the A-type sub pixel SPa may be disposed to face the B-type sub pixel SPb, and the first connection electrode CE1 of the B-type sub pixel SPb may also be disposed to face the A-type sub pixel SPa. Therefore, an arrangement direction of the light-emitting element 120, which has a first electrode 124 connected to the first connection electrode CE1, may vary depending on the position of the first connection electrode CE1.

For example, the light-emitting element 120 of the A-type sub pixel SPa may be disposed so that the first electrode 124 is directed toward the B-type sub pixel SPb, and the light-emitting element 120 of the B-type sub pixel SPb may be disposed so that the first electrode 124 is directed toward the A-type sub pixel SPa. For example, in the A-type sub pixel SPa in the n-th column, the first electrode 124 of the light-emitting element 120 is disposed to be directed toward the (n+1)th column. In the B-type sub pixel SPb in the (n+1)th column, the first electrode 124 of the light-emitting element 120 may be disposed to be directed toward the n-th column.

In addition, the arrangement direction of the light-emitting element 120 of the A-type sub pixel SPa disposed in one pixel area UPA and the arrangement direction of the light-emitting element 120 of the B-type sub pixel SPb may be opposite to each other. For example, in the pixel area UPA in the n-th column, the light-emitting element 120 of the A-type sub pixel SPa may be disposed so that the first electrode 124 is directed toward the (n+1)th column, and the light-emitting element 120 of the B-type sub pixel SPb may be disposed so that the first electrode 124 is directed toward the (n−1)th column.

In one pixel area UPA, the arrangement direction of the light-emitting element 120 of the A-type sub pixel SPa and the arrangement direction of the light-emitting element 120 of the B-type sub pixel SPb are opposite to each other, such that one second connection electrode CE2 connected in common to the plurality of light-emitting elements 120 may have a zigzag shape. The second connection electrode CE2 may extend straight in the column direction and have a zigzag shape to correspond to a second electrode 125 of the light-emitting element 120 of each of the sub pixels SP. For example, in one pixel area UPA, the second electrode 125 of the light-emitting element 120 of the A-type sub pixel SPa may be disposed to be biased toward one side of the pixel area UPA, and the second electrode 125 of the light-emitting element 120 of the B-type sub pixel SPb may be disposed to be biased toward the other side of the pixel area UPA. Therefore, the second connection electrode CE2 may be formed in a zigzag shape to correspond to the position of the second electrode 125 of the light-emitting element 120. For example, the second connection electrode CE2 may include a portion disposed on the A-type sub pixel SPa and adjacent to one side of the pixel area UPA, and a portion disposed on the B-type sub pixel SPb and adjacent to the other side of the pixel area UPA. Further, because the group of the A-type sub pixels SPa and the group of the B-type sub pixels SPb are alternately disposed in the same column, the portion of the second connection electrode CE2 disposed adjacent to one side of the pixel area UPA and the portion of the second connection electrode CE2 disposed adjacent to the other side of the pixel area UPA may be alternately disposed.

Next, the B-type sub pixel SPb includes a welding area WA. The welding area WA is an area on which a welding process is performed by irradiating the area with laser beams during the repair process. An area in which the repair line WRL and the first reflective electrode RE1 of the B-type sub pixel SPb overlap may be defined as the welding area WA to be irradiated with laser beams during the repair process. The repair process may be performed by electrically connecting the repair line WRL and the first connection electrode CE1 of the B-type sub pixel SPb by irradiating the welding area WA with laser beams. The repair process using the repair line WRL will be described below in detail with reference to FIGS. 5A to 6.

Next, the plurality of transmissive areas TA are areas excluding the area in which the plurality of lines and the plurality of pixel areas UPA are disposed in the display area AA. The plurality of transmissive areas TA has a relatively high transmittance rate. The transmissive area TA transmits light, such that a background positioned on the rear surface of the display device 100 is visible from the front surface of the display device 100. The plurality of transmissive areas TA may be disposed to be spaced apart from one another with the plurality of lines and the plurality of pixel areas UPA interposed therebetween. The plurality of transmissive areas TA may be disposed to surround the plurality of pixel areas UPA. Therefore, the display device 100 according to embodiments of the present disclosure may be implemented as the transparent display device 100 including the plurality of transmissive areas TA.

With reference to FIGS. 4 to 5B, the plurality of sub pixels SP each includes the pixel circuit and the light-emitting element 120. For example, the pixel circuit may include a first transistor T1, a second transistor T2, the driving transistor DT, and a storage capacitor Cst and operate the light-emitting element 120. Further, the plurality of sub pixels SP disposed in one pixel area UPA may be connected to the scan line SL, the plurality of data lines DL, the reference line RL, the high-potential power line VDD, and the low-potential power line VSS and supplied with various types of signals.

First, a substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

A light-blocking layer LS is disposed on each of the plurality of sub pixels SP on the substrate 110. The light-blocking layer LS blocks light entering a driving active layer DACT of the driving transistor DT, which will be described below, from a lower side of the substrate 110. The light-blocking layer LS may block light entering the driving active layer DACT of the driving transistor DT, thereby minimizing a leakage current.

A buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT, the first transistor T1, and the second transistor T2 are disposed in each of the plurality of sub pixels SP on the buffer layer 111.

The driving transistor DT, the first transistor T1, and the second transistor T2 of each of the plurality of sub pixels SP may be P-type thin-film transistors or N-type thin-film transistors. For example, in the P-type thin-film transistor, positive holes move from a source electrode to a drain electrode, such that current may flow from the source electrode to the drain electrode. In the N-type thin-film transistor, electrons move from a source electrode to a drain electrode, such that current may flow from the drain electrode to the source electrode. Hereinafter, the description will be made on the assumption that the driving transistor DT, the first transistor T1, and the second transistor T2 are the P-type thin-film transistors in which the current flows from the source electrodes to the drain electrodes. However, the present disclosure is not limited thereto.

First, the driving transistor DT is disposed in each of the plurality of sub pixels SP on the buffer layer 111. The driving transistor DT is a transistor for controlling a drive current to be supplied to the light-emitting element 120. In one pixel area UPA, the driving transistors DT of the plurality of sub pixels SP may be disposed in a line in the column direction. The plurality of driving transistors DT of the plurality of sub pixels SP may be disposed in a line while overlapping the areas in which the reference lines RL and the data lines DL are disposed.

The driving transistor DT includes the driving active layer DACT, a driving gate electrode DGE, a driving source electrode DSE, and a driving drain electrode DDE.

The driving active layer DACT is disposed on the buffer layer 111. The driving active layer DACT may be made of a semiconductor material such as an oxide semiconductor, amorphous silicon, or polysilicon. However, the present disclosure is not limited thereto.

A gate insulation layer 112 is disposed on the driving active layer DACT. The gate insulation layer 112 is an insulation layer for insulating the driving active layer DACT and the driving gate electrode DGE. The gate insulation layer 112 may be configured as a single layer or multilayer made of silicon oxide (SiOx) or silicon nitride (SiNx). However, the present disclosure is not limited thereto.

The driving gate electrode DGE is disposed on the gate insulation layer 112. The driving gate electrode DGE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first interlayer insulation layer 113a is disposed on the driving gate electrode DGE. A contact hole, through which the driving source electrode DSE is connected to the driving active layer DACT, is formed in the first interlayer insulation layer 113a. The first interlayer insulation layer 113a is an insulation layer for protecting components disposed below the first interlayer insulation layer 113a. The first interlayer insulation layer 113a may be configured as a single layer or multilayer made of silicon oxide (SiOx) or silicon nitride (SiNx). However, the present disclosure is not limited thereto.

The driving source electrode DSE is disposed on the first interlayer insulation layer 113a. The driving source electrode DSE is electrically connected to the driving active layer DACT through contact holes formed in the first interlayer insulation layer 113a and the gate insulation layer 112. Further, the driving source electrode DSE may be electrically connected to the second transistor T2. The driving source electrode DSE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second interlayer insulation layer 113b and a first passivation layer 114a are disposed on the first interlayer insulation layer 113a, and the driving drain electrode DDE is disposed on the first passivation layer 114a. The driving drain electrode DDE is electrically connected to the driving active layer DACT through contact holes formed in the first passivation layer 114a, the second interlayer insulation layer 113b, the first interlayer insulation layer 113a, and the gate insulation layer 112. Further, the driving drain electrode DDE may be electrically connected to the low-potential power line VSS through a contact hole formed in the first passivation layer 114a. The driving drain electrode DDE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second interlayer insulation layer 113b is disposed on the first interlayer insulation layer 113a. The second interlayer insulation layer 113b is an insulation layer for protecting components disposed below the second interlayer insulation layer 113b. The second interlayer insulation layer 113b may be configured as a single layer or multilayer made of silicon oxide (SiOx) or silicon nitride (SiNx). However, the present disclosure is not limited thereto.

The first passivation layer 114a is disposed on the second interlayer insulation layer 113b. The first passivation layer 114a is an insulation layer for protecting components disposed below the first passivation layer 114a. The first passivation layer 114a may be configured as a single layer or multilayer made of silicon oxide (SiOx) or silicon nitride (SiNx). However, the present disclosure is not limited thereto.

Next, the first transistor T1 is disposed on the buffer layer 111 in each of the plurality of sub pixels SP. The first transistor T1 may be a transistor configured to transmit a data voltage to the driving gate electrode DGE of the driving transistor DT. The first transistor T1 may be referred to as a switching transistor. In this case, in one pixel area UPA, the plurality of first transistors T1 of the plurality of sub pixels SP may be disposed in a line in the row direction and overlap the scan line SL.

For example, the scan line SL may extend in the row direction on the gate insulation layer 112 and be disposed to traverse the plurality of pixel areas UPA. Further, the first transistors T1 of the pair of first sub pixels SP1a and SP1b, the first transistors T1 of the pair of second sub pixels SP2a and SP2b, and the first transistors T1 of the pair of third sub pixels SP3a and SP3b may be sequentially disposed along the scan line SL. For example, the first transistor T1 of the first B-type sub pixel SP1b at the other side of the scan line SL, the first transistor T1 of the first A-type sub pixel SP1a at one side of the scan line SL, the first transistor T1 of the second B-type sub pixel SP2b at the other side of the scan line SL, the first transistor T1 of the second A-type sub pixel SP2a at one side of the scan line SL, the first transistor T1 of the third B-type sub pixel SP3b at the other side of the scan line SL, and the first transistor T1 of the third A-type sub pixel SP3a at one side of the scan line SL may be sequentially disposed in the row direction.

In this case, the first transistors T1 of the pair of first sub pixels SP1a and SP1b may be disposed adjacent to each other and share one data line DL. Further, the first transistors T1 of the pair of second sub pixels SP2a and SP2b may also be disposed adjacent to each other and share one data line DL. Lastly, the first transistors T1 of the pair of third sub pixels SP3a and SP3b may also be disposed adjacent to each other and share one data line DL.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as an oxide semiconductor, amorphous silicon, or polysilicon. However, the present disclosure is not limited thereto.

The first gate electrode GE1 is disposed on the gate insulation layer 112. The first gate electrode GE1 may be electrically connected to the scan line SL. For example, the first gate electrode GE1 may be integrated with the scan line SL. The first gate electrode GE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first drain electrode DE1 is disposed on the first interlayer insulation layer 113a. The first drain electrode DE1 is electrically connected to the first active layer ACT1 through contact holes formed in the first interlayer insulation layer 113a and the gate insulation layer 112. Further, the first drain electrode DE1 may also be electrically connected to a second gate electrode GE2 of the second transistor T2 through the contact hole of the first interlayer insulation layer 113a. The first drain electrode DE1 may be made of an electrically conductive material, for example, copper thereof. However, the present disclosure is not limited thereto.

The first source electrode SE1 is disposed on the first passivation layer 114a. The first source electrode SE1 is electrically connected to the first active layer ACT1 through the contact holes of the first passivation layer 114a, the second interlayer insulation layer 113b, and the first interlayer insulation layer 113a. Further, the first source electrode SE1 may be electrically connected to the data line DL. For example, the first source electrode SE1 may be integrated with the data line DL. The first source electrode SE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In this case, the first source electrode SE1 of the first transistor T1 of the sub pixel SP disposed at one side of the scan line SL may be connected to the data line DL in the area at the other side of the scan line SL. Further, the first source electrode SE1 of the first transistor T1 of the sub pixel SP disposed at the other side of the scan line SL may be connected to the data line DL in the area at one side of the scan line SL. For example, the first source electrode SE1 of the first transistor T1 of the A-type sub pixel SPa at one side of the scan line SL may be connected to the data line DL in the area at the other side of the scan line SL. The first source electrode SE1 of the first transistor T1 of the B-type sub pixel SPb at the other side of the scan line SL may be connected to the data line DL in the area at the other side of the scan line SL.

Therefore, in the first transistors T1 of the pair of first sub pixels SP1a and SP1b, the first source electrodes SE1 and the first drain electrodes DE1 may be disposed in a staggered manner. The first source electrode SE1 of the first transistor T1 of one of the pair of first sub pixels SP1a and SP1b may be disposed at one side of the scan line SL, and the first source electrode SE1 of the first transistor T1 of the other of the first sub pixels SP1a and SP1b may be disposed at the other side of the scan line SL. Like the first transistors T1 of the pair of first sub pixels SP1a and SP1b, the first source electrodes SE of the first transistors T1 of the pair of second sub pixels SP2a and SP2b and the first source electrodes SE1 of the first transistors T1 of the pair of third sub pixels SP3a and SP3b may also be disposed in one side area and the other side area of the scan line SL.

Therefore, in one side area of the scan line SL, the first source electrodes SE1 of the first sub pixels SP1a and SP1b, the first drain electrodes DE1 of the first sub pixels SP1a and SP1b, the first source electrodes SE1 of the second sub pixels SP2a and SP2b, the first drain electrodes DE1 of the second sub pixels SP2a and SP2b, the first source electrodes SE1 of the third sub pixels SP3a and SP3b, and the first drain electrodes DE1 of the third sub pixels SP3a and SP3b may be sequentially disposed. Further, in the other side area of the scan line SL, the first drain electrodes DE1 of the first sub pixels SP1a and SP1b, the first source electrodes SE1 of the first sub pixels SP1a and SP1b, the first drain electrodes DE1 of the second sub pixels SP2a and SP2b, the first source electrodes SE1 of the second sub pixels SP2a and SP2b, the first drain electrodes DE1 of the third sub pixels SP3a and SP3b, and the first source electrodes SE1 of the third sub pixels SP3a and SP3b may be sequentially disposed.

Next, the second transistor T2 is disposed on the buffer layer 111 in each of the plurality of sub pixels SP. The second transistor T2 may be a transistor configured to sense and compensate for a threshold voltage of the driving transistor DT. The second transistor T2 may be referred to as a sensing transistor. The second transistors T2 of the plurality of sub pixels SP may be respectively disposed at the left or right sides of the plurality of sub pixels SP and disposed in a line in the column direction. For example, the second transistors T2 of the first sub pixels SP1a and SP1b, the second transistors T2 of the second sub pixels SP2a and SP2b, and the second transistors T2 of the third sub pixels SP3a and SP3b disposed at one side of the scan line SL may be disposed at the right side of each of the sub pixels SP. The second transistors T2 of the first sub pixels SP1a and SP1b, the second transistors T2 of the second sub pixels SP2a and SP2b, and the second transistors T2 of the third sub pixels SP3a and SP3b disposed at the other side of the scan line SL may be disposed at the left side of each of the sub pixels SP.

For example, the scan line SL extending in the row direction may include a protruding part protruding in the column direction in each of the plurality of pixel areas UPA. A part of the scan line SL, which protrudes in the column direction, may be disposed adjacent to the left or right sides of the plurality of sub pixels SP and overlap the plurality of second transistors T2. For example, the protruding parts of the scan line SL, which protrude toward the area at one side, may be disposed at the right sides of the plurality of sub pixels SP and serve as the second gate electrodes GE2 of the second transistors T2 of the plurality of sub pixels SP. The protruding parts of the scan line SL, which protrude toward the area at the other side, may be disposed at the left sides of the plurality of sub pixels SP and serve as the second gate electrodes GE2 of the second transistors T2 of the plurality of sub pixels SP.

The second transistor T2 includes a second active layer ACT2, the second gate electrode GE2, a second source electrode SE2, and a second drain electrode DE2.

The second active layer ACT2 is disposed between the buffer layer 111 and the gate insulation layer 112. The second active layer ACT2 may be made of a semiconductor material such as an oxide semiconductor, amorphous silicon, or polysilicon. However, the present disclosure is not limited thereto.

In this case, the second active layers ACT2 of the plurality of adjacent sub pixels SP may be connected to one another. For example, the second active layers ACT2 of the first sub pixels SP1a and SP1b, the second active layers ACT2 of the second sub pixels SP2a and SP2b, and the second active layers ACT2 of the third sub pixels SP3a and SP3b disposed at one side of the scan line SL may extend in the column direction and be connected to one another and connected together to one second drain electrode DE2. Further, the second active layers ACT2 of the first sub pixels SP1a and SP1b, the second active layers ACT2 of the second sub pixels SP2a and SP2b, and the second active layers ACT2 of the third sub pixels SP3a and SP3b disposed at the other side of the scan line SL may also extend in the column direction and be connected to one another and connected together to one second drain electrode DE2.

That is, connection parts for connecting the reference line RL and channel areas of the second active layers ACT2 of the plurality of sub pixels SP are made of the transparent material of the second active layer ACT2, instead of an opaque electrically conductive material, such that a transmittance rate may be increased at an outermost periphery of the pixel area UPA. In addition, the connection parts for connecting the reference line RL and the channel areas of the second active layers ACT2 of the plurality of sub pixels SP are made of the material of the second active layer ACT2, such that the contact hole may be eliminated, and the structure of the pixel area UPA may be simplified.

In this case, the second active layer ACT2 may also be connected to the driving active layer DACT of the driving transistor DT. That is, the driving active layer DACT and the second active layer ACT2 may be integrated with each other, and the driving source electrode DSE and the second source electrode SE2 respectively connected to the driving active layer DACT and the second active layer ACT2 may be electrically connected to each other.

Next, the second gate electrode GE2 is disposed between the gate insulation layer 112 and the first interlayer insulation layer 113a. The second gate electrode GE2 may be electrically connected to the scan line SL. For example, the second gate electrode GE2 may be integrated with and electrically connected to the protruding part extending in the column direction from the scan line SL. The second gate electrode GE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second source electrode SE2 is disposed between the first interlayer insulation layer 113a and the second interlayer insulation layer 113b. The second source electrode SE2 is electrically connected to the second active layer ACT2 through the contact holes of the first interlayer insulation layer 113a and the gate insulation layer 112. Further, the second source electrode SE2 and the driving source electrode DSE may be electrically connected to each other. The second source electrode SE2 and the driving source electrode DSE may be disposed on the same layer, made of the same material, connected to each other, and integrated with each other. That is, a conductive layer, which is disposed between the first interlayer insulation layer 113a and the second interlayer insulation layer 113b and electrically connected to the driving active layer DACT and the second active layer ACT2, may serve as the second source electrode SE2 or the driving source electrode DSE. The second source electrode SE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second drain electrode DE2 is disposed between the first interlayer insulation layer 113a and the second interlayer insulation layer 113b. The second drain electrode DE2 is electrically connected to the second active layer ACT2 through contact holes of the first interlayer insulation layer 113a and the gate insulation layer 112. Further, the second drain electrode DE2 may be connected to an auxiliary reference line RLA through contact holes formed in the first interlayer insulation layer 113a, the gate insulation layer 112, and the buffer layer 111. Therefore, the second drain electrode DE2 may be electrically connected to the reference line RL through the auxiliary reference line RLA. The second drain electrode DE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, the reference line RL is disposed on the first passivation layer 114a. The reference line RL may extend in the column direction and disposed to traverse the plurality of pixel areas UPA. In this case, the reference line RL may be disposed to be spaced apart from the second transistor T2 without overlapping the second transistor T2. For example, the reference line RL may be disposed between the data line DL, which is connected to the first sub pixels SP1a and SP1b, and the data line DL connected to the second sub pixels SP2a and SP2b. The auxiliary reference line RLA, which extends in the row direction, may be further disposed to electrically connect the reference line RL and the second transistor T2.

The auxiliary reference line RLA is disposed between the substrate 110 and the buffer layer 111 in each of the plurality of pixel areas UPA. At least a part of the auxiliary reference line RLA may be disposed to overlap the area in which the scan line SL is disposed. The auxiliary reference line RLA may intersect the reference line RL, and the reference line RL and the auxiliary reference line RLA may be electrically connected to each other at the intersection point. For example, the reference line RL may be electrically connected to the auxiliary reference line RLA through contact holes formed in the first passivation layer 114a, the second interlayer insulation layer 113b, the first interlayer insulation layer 113a, the gate insulation layer 112, and the buffer layer 111. Further, one end of the auxiliary reference line RLA may be connected to the second drain electrode DE2 of the second transistor T2 disposed at one side of the scan line SL, and the other end of the auxiliary reference line RLA may be connected to the second drain electrode DE2 of the second transistor T2 disposed at the other side of the scan line SL.

In this case, the plurality of second transistors T2 disposed at one side of the scan line SL may share one second drain electrode DE2, and the plurality of second transistors T2 disposed at the other side of the scan line SL may share one second drain electrode DE2. For example, the second active layers ACT2 of the plurality of second transistors T2 disposed at one side or the other side of the scan line SL may be connected to one another and integrated. The second active layers ACT2, which are integrated, may be connected to one second drain electrode DE2. Therefore, the plurality of second transistors T2 may share one second drain electrode DE2 without including the second drain electrode DE2 separately, such that the structure of the sub pixel SP may be simplified, and a part of the opaque conductive layer may be eliminated, which may increase the transmittance rate.

Next, the storage capacitor Cst is disposed on the substrate 110. The storage capacitor Cst is connected to the driving source electrode DSE and the driving gate electrode DGE of the driving transistor DT. The storage capacitor Cst may store electric charges and maintain a predetermined potential difference between the driving source electrode DSE and the driving gate electrode DGE of the driving transistor DT. Therefore, because the potential difference between the driving gate electrode DGE and the driving source electrode DSE is maintained, a predetermined drive current may be supplied to the light-emitting element 120 while the light-emitting element 120 emits light.

The storage capacitor Cst includes a first capacitor electrode C1, a second capacitor electrode C2, and a third capacitor electrode C3. The first capacitor electrode C1 is disposed between the substrate 110 and the buffer layer 111. The first capacitor electrode C1 may be integrated with the light-blocking layer LS. The second capacitor electrode C2 is disposed between the gate insulation layer 112 and the first interlayer insulation layer 113a and overlaps the first capacitor electrode C1. The second capacitor electrode C2 may be integrated with the driving gate electrode DGE and electrically connected to the driving gate electrode DGE. The third capacitor electrode C3 is disposed between the first interlayer insulation layer 113a and the second interlayer insulation layer 113b and overlaps the first capacitor electrode C1 and the second capacitor electrode C2. The third capacitor electrode C3 may be integrated with the driving source electrode DSE and electrically connected to the driving source electrode DSE. Further, the third capacitor electrode C3 may be electrically connected to the first capacitor electrode C1 through contact holes formed in the first interlayer insulation layer 113a, the gate insulation layer 112, and the buffer layer 111. The first capacitor electrode C1, the second capacitor electrode C2, and the third capacitor electrode C3 may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto. Therefore, the storage capacitor Cst includes the first and third capacitor electrodes C1 and C3, which are connected to the driving source electrode DSE, and the second capacitor electrode C2 connected to the driving gate electrode DGE, thereby maintaining a predetermined voltage difference between the driving gate electrode DGE and the driving source electrode DSE.

Next, an auxiliary electrode AE is disposed on the first passivation layer 114a. The auxiliary electrode AE is an electrode for electrically connecting the driving source electrode DSE and the first reflective electrode RE1. The driving source electrode DSE and the first reflective electrode RE1 may be electrically connected to each other through the auxiliary electrode AE. The auxiliary electrode AE may be made of an electrically conductive material, for example, copper thereof. However, the present disclosure is not limited thereto.

The low-potential power line VSS is disposed on the second interlayer insulation layer 113b. The low-potential power line VSS may be disposed in the column direction and overlap the plurality of pixel areas UPA. The low-potential power line VSS may be electrically connected to the driving drain electrode DDE through a contact hole formed in the first passivation layer 114a. The low-potential power line VSS may be disposed to overlap all the plurality of lines extending in the column direction, e.g., the data line DL and the reference line RL. The low-potential power line VSS may have a relatively large width, such that the low-potential power line VSS may overlap both the data line DL and the reference line RL. The low-potential power line VSS may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In this case, the low-potential power line VSS may be disposed between the data line DL and an area, in which a channel of the driving transistor DT is at least disposed among the components of the pixel circuit, and minimize a fluctuation of voltage of the driving transistor DT caused by a change in voltage of the data line DL. First, in order to ensure an area of the transmissive area TA, the line, such as the data line DL, may be disposed to overlap the pixel area UPA. However, in case that the data line DL, to which different voltages are applied depending on the frame, is disposed to overlap the driving transistor DT or the like, the change in voltage of the data line DL may affect the driving transistor DT, and the drive current may fluctuate. Therefore, the low-potential power line VSS, to which a constant voltage is applied, is disposed to at least cover the driving gate electrode DGE in which the channel of the driving transistor DT is formed, and the data line DL is disposed on the low-potential power line VSS, which may inhibit the change in voltage of the data line DL from affecting the driving transistor DT. Therefore, the low-potential power line VSS, which serves as a blocking film, may be disposed between the driving transistor DT and the data line DL, thereby minimizing the fluctuation of voltage of the driving transistor DT.

Meanwhile, because the low-potential power line VSS covers the most part of the pixel area UPA, a plurality of opening portions may be formed in the low-potential power line VSS to electrically connect the data line DL and the reference line RL, which are disposed on the low-potential power line VSS, and another component disposed below the low-potential power line VSS. For example, the plurality of opening portions of the low-potential power line VSS may be disposed to correspond to the contact hole, through which the first source electrode SE1 and the first active layer ACT1 are connected, and the contact hole through which the driving drain electrode DDE and the driving active layer DACT are connected. For example, as illustrated in FIG. 5A, the driving drain electrode DDE may be connected to the driving active layer DACT in the area in which the opening portion of the low-potential power line VSS is disposed.

Next, the reference line RL is disposed on the first passivation layer 114a. The reference line RL may be disposed in the column direction and overlap the plurality of pixel areas UPA. The reference line RL may be electrically connected to the plurality of second transistors T2 through the auxiliary reference line RLA. The reference line RL may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The plurality of data lines DL is disposed on the first passivation layer 114a. The plurality of data lines DL may extend in the column direction and overlap the plurality of pixel areas UPA. The plurality of data lines DL may include the data lines DL connected to the first transistors T1 of the plurality of first sub pixels SP1a and SP1b, the data lines DL connected to the first transistors T1 of the plurality of second sub pixels SP2a and SP2b, and the data lines DL connected to the first transistors T1 of the plurality of third sub pixels SP3a and SP3b. For example, the data lines DL connected to the first sub pixels SP1a and SP1b, the reference line RL, the data lines DL connected to the second sub pixels SP2a and SP2b, and the data lines DL connected to the third sub pixels SP3a and SP3b may be sequentially disposed from the left side of the pixel area UPA.

Next, a second passivation layer 114b is disposed on the driving transistor DT, the first transistor T1, the second transistor T2, the storage capacitor Cst, the low-potential power line VSS, the reference line RL, and the data line DL. The second passivation layer 114b may be an insulation layer for protecting components disposed below the second passivation layer 114b. The second passivation layer 114b may be configured as a single layer or multilayer made of silicon oxide (SiOx) or silicon nitride (SiNx). However, the present disclosure is not limited thereto.

A first planarization layer 115a is disposed on the second passivation layer 114b. The first planarization layer 115a may planarize an upper portion of the substrate 110 on which the plurality of transistors and the storage capacitor Cst are disposed. The first planarization layer 115a may be configured as a single layer or multilayer and made of a photoresist or an acrylic-based organic material, for example. However, the present disclosure is not limited thereto.

Meanwhile, although not illustrated in the drawings, an additional passivation layer may be further disposed on the first planarization layer 115a. For example, the passivation layer, which is configured as a single layer or multilayer made of silicon oxide (SiOx) or silicon nitride (SiNx), may be disposed on the first planarization layer 115a and protect the components disposed below the passivation layer.

Next, the plurality of first reflective electrodes RE1 is disposed on the first planarization layer 115a. The plurality of first reflective electrodes RE1 may be respectively disposed in the plurality of sub pixels SP and electrically connect the driving transistors DT and the light-emitting elements 120. At the same time, the plurality of first reflective electrodes RE1 may reflect the light, which is emitted from the light-emitting elements 120, to the outside of the display device 100. The plurality of first reflective electrodes RE1 may be electrically connected to the auxiliary electrode AE through first contact holes CH1 formed in one or more insulation layer, e.g., the first planarization layer 115a and the second passivation layer 114b. Therefore, the plurality of first reflective electrodes RE1 may be electrically connected to the driving source electrode DSE of the driving transistor DT through the auxiliary electrode AE. The plurality of first reflective electrodes RE1 may be made of an opaque conductive material such as titanium (Ti), gold (Au), silver (Ag), copper (Cu), or an alloy thereof with high reflection efficiency. However, the present disclosure is not limited thereto.

In this case, the first contact hole CH1, through which the first reflective electrode RE1 and the auxiliary electrode AE are connected, does not overlap the first connection electrode CE1 and the repair line WRL to be described below. The first contact hole CH1, through which the first reflective electrode RE1 is electrically connected to the driving transistor DT, may be disposed to be spaced apart from the welding area WA. With reference to FIG. 5A, in the B-type sub pixel SPb, the first reflective electrode RE1 may include a portion overlapping the welding area WA, a portion connected to the first contact hole CH1, and a portion connected to the first connection electrode CE1. Further, with reference to FIG. 5B, in the A-type sub pixel SPa, the first reflective electrode RE1 may include a portion connected to the first contact hole CH1 and a portion connected to the first connection electrode CE1.

The first contact hole CH1 is a portion that is to be destroyed by being irradiated with laser beams during a dark-spot process. The first contact hole CH1 may be disposed without overlapping the first connection electrode CE1 and the repair line WRL. The first contact hole CH1 may be disposed in the area in which the first connection electrode CE1 and the repair line WRL are not disposed, which may suppress damage to the first connection electrode CE1 and the repair line WRL during the dark-spot process.

For example, with reference to FIG. 5A, in the B-type sub pixel SPb, the repair line WRL may be disposed to overlap only the welding area WA, and the repair line WRL may not overlap the first contact hole CH1 through which the first reflective electrode RE1 and the auxiliary electrode AE are connected. Further, the first connection electrode CE1 and the contact hole, through which the first connection electrode CE1 and the first reflective electrode RE1 are connected, may not overlap the first contact hole CH1.

For example, with reference to FIG. 5B, in the A-type sub pixel SPa, the first connection electrode CE1 and the repair line WRL may not overlap the first contact hole CH1. In this case, although not illustrated in the cross-sectional view in FIG. 5B, the repair line WRL and the first connection electrode CE1 may be connected to each other in the area in which the first contact hole CH1 is not disposed, as illustrated in the top plan views in FIGS. 3 and 4.

Therefore, the area of the first contact hole CH1, which is to be irradiated with laser beams, is disposed in an area different from the area in which the repair line WRL and the first connection electrode CE1 are disposed, such that the repair line WRL and the first connection electrode CE1 may be protected so as not to be damaged by laser beams.

Next, the second reflective electrode RE2 or the high-potential power line VDD is disposed on the first planarization layer 115a. The second reflective electrode RE2 and the high-potential power line VDD may be integrated and configured to supply a high-potential power voltage to the light-emitting element 120 and reflect the light, which is emitted from the light-emitting element 120, to the outside of the display device 100. The second reflective electrodes RE2 of the plurality of sub pixels SP may be connected to and integrated with one another. The second reflective electrode RE2 and the high-potential power line VDD may extend in the column direction and be disposed to overlap the light-emitting element 120. The second reflective electrode RE2 and the high-potential power line VDD may be disposed to overlap the plurality of data lines DL, the reference line RL, and the low-potential power line VSS. The second reflective electrode RE2 and the high-potential power line VDD may be made of an opaque conductive material such as titanium (Ti), gold (Au), silver (Ag), copper (Cu), or an alloy thereof with high reflection efficiency. However, the present disclosure is not limited thereto.

A third passivation layer 114c is disposed on the plurality of first reflective electrodes RE1 and the second reflective electrode RE2. The third passivation layer 114c may be an insulation layer for protecting components disposed below the third passivation layer 114c. The third passivation layer 114c may be configured as a single layer or multilayer made of silicon oxide (SiOx) or silicon nitride (SiNx). However, the present disclosure is not limited thereto.

A bonding layer AD is disposed on the third passivation layer 114c. The bonding layer AD may be formed on the front surface of the substrate 110 and fix the light-emitting element 120 disposed on the bonding layer AD. The bonding layer AD may be made of a photocurable bonding material that may be cured by light. For example, the bonding layer AD may be made of any one material selected from adhesive polymer, epoxy resist, UV resin, a polyimide-based material, an acrylate-based material, an urethane-based material, and polydimethylsiloxane (PDMS). However, the present disclosure is not limited thereto.

The plurality of light-emitting elements 120 is provided on the bonding layer AD and disposed in each of the plurality of sub pixels SP. The light-emitting elements 120 may be elements configured to emit light by the current and include a red light-emitting element 120R configured to emit red light, a green light-emitting element 120G configured to emit green light, and a blue light-emitting element 120B configured to emit blue light. A combination of the light-emitting elements 120 may implement various colors including white. For example, the light-emitting element 120 may be a light-emitting diode (LED) or a micro LED. However, the present disclosure is not limited thereto.

The red light-emitting elements 120R may be disposed in the first sub pixels SP1a and SP1b, the green light-emitting elements 120G may be disposed in the second sub pixels SP2a and SP2b, and the blue light-emitting elements 120B may be disposed in the third sub pixels SP3a and SP3b. The plurality of light-emitting elements 120 disposed in one pixel area UPA may be disposed in a line in the column direction. Further, the plurality of light-emitting elements 120 may be respectively disposed in the plurality of sub pixels SP and disposed to overlap the second reflective electrode RE2.

The plurality of light-emitting elements 120 each includes a first semiconductor layer 121, a light-emitting layer 122, a second semiconductor layer 123, the first electrode 124, the second electrode 125, and an encapsulation film 126.

The first semiconductor layer 121 is disposed on the bonding layer AD, and the second semiconductor layer 123 is disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 is disposed on the first semiconductor layer 121. The first electrode 124 is an electrode that electrically connects the driving transistor DT and the first semiconductor layer 121. In this case, the first semiconductor layer 121 may be a semiconductor layer doped with n-type impurities, and the first electrode 124 may be a cathode. The first electrode 124 may be disposed on a top surface of the first semiconductor layer 121 exposed from the light-emitting layer 122 and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 may be disposed on a top surface of the second semiconductor layer 123. The second electrode 125 is an electrode for electrically connecting the high-potential power line VDD and the second semiconductor layer 123. In this case, the second semiconductor layer 123 may be a semiconductor layer doped with p-type impurities, and the second electrode 125 may be an anode. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the encapsulation film 126 is disposed to surround the first semiconductor layer 121, the light-emitting layer 122, the second semiconductor layer 123, the first electrode 124, and the second electrode 125. The encapsulation film 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the encapsulation film 126, such that the first connection electrode CE1, the second connection electrode CE2, the first electrode 124, and the second electrode 125 may be electrically connected.

Meanwhile, a part of a side surface of the first semiconductor layer 121 may be exposed from the encapsulation film 126. The light-emitting element 120 manufactured on a wafer may be separated from the wafer and transferred to the display panel PN. However, a part of the encapsulation film 126 may be torn during a process of separating the light-emitting element 120 from the wafer. For example, a part of the encapsulation film 126 adjacent to a lower edge of the first semiconductor layer 121 of the light-emitting element 120 may be torn during the process of separating the light-emitting element 120 from the wafer, such that a part of a lower side surface of the first semiconductor layer 121 may be exposed to the outside. Even though the lower portion of the light-emitting element 120 is exposed from the encapsulation film 126, the first connection electrode CE1 and the second connection electrode CE2 are formed after second and third planarization layers 115b and 115c, which cover the side surface of the first semiconductor layer 121, are formed, thereby reducing a short circuit defect.

Next, the second planarization layer 115b and the third planarization layer 115c are disposed on the bonding layer AD and the light-emitting element 120.

The second planarization layer 115b may partially overlap the side surfaces of the plurality of light-emitting elements 120 and fix and protect the plurality of light-emitting elements 120. The second planarization layer 115b may cover a torn portion of the encapsulation film 126 that protects the side surface of the first semiconductor layer 121 of the light-emitting element 120. Therefore, it is possible to suppress the contact between the connection electrode and the first semiconductor layer 121 and a short circuit defect later.

The third planarization layer 115c is formed to cover upper sides of the second planarization layer 115b and the light-emitting element 120. A contact hole, through which the first electrode 124 and the second electrode 125 of the light-emitting element 120 are exposed, may be formed in the third planarization layer 115c. The first electrode 124 and the second electrode 125 of the light-emitting element 120 may be exposed from the third planarization layer 115c. However, the third planarization layer 115c is partially disposed in an area between the first electrode 124 and the second electrode 125, thereby reducing a short circuit defect. The second planarization layer 115b and the third planarization layer 115c may each be configured as a single layer or multilayer and made of a photoresist or an acrylic-based organic material, for example. However, the present disclosure is not limited thereto.

The plurality of first connection electrodes CE1 and the second connection electrode CE2 are disposed on the third planarization layer 115c.

The plurality of first connection electrodes CE1 are electrodes configured to electrically connect the driving transistors DT and the first electrodes 124 of the light-emitting elements 120 in the plurality of sub pixels SP. The first connection electrode CE1 may be electrically connected to the first electrode 124, which is exposed from the third planarization layer 115c, and simultaneously electrically connected to the first reflective electrode RE1 through contact holes formed in the third planarization layer 115c, the second planarization layer 115b, and the third passivation layer 114c. Therefore, the first electrode 124 and the driving source electrode DSE may be electrically connected through the first connection electrode CE1, the first reflective electrode RE1, and the auxiliary electrode AE.

The second connection electrode CE2 is an electrode that electrically connects the high-potential power line VDD and the second electrode 125 of the light-emitting element 120. The second connection electrode CE2 may be electrically connected to the second electrode 125, which is exposed from the third planarization layer 115c, and electrically connected to the second reflective electrode RE2 or the high-potential power line VDD through contact holes formed in the third planarization layer 115c, the second planarization layer 115b, and the third passivation layer 114c. Therefore, the second electrode 125 and the high-potential power line VDD may be electrically connected through the second connection electrode CE2.

The first connection electrode CE1 and the second connection electrode CE2 may be made of a transparent conductive material such as indium tin oxide (ITO) or indium zinc oxide (IZO). However, the present disclosure is not limited thereto.

Meanwhile, the drawings illustrate that the driving source electrode DSE of the driving transistor DT and the first electrode 124 of the light-emitting element 120 are electrically connected. However, the driving drain electrode DDE of the driving transistor DT and the second electrode 125 of the light-emitting element 120 may be electrically connected in accordance with the type of the driving transistor DT and the design of the pixel circuit. However, the present disclosure is not limited thereto.

Next, a black matrix BM is disposed on the third planarization layer 115c, the first connection electrode CE1, and the second connection electrode CE2 in the pixel area UPA. The black matrix BM may be disposed to be spaced apart from the light-emitting element 120 at a predetermined interval. The black matrix BM may be disposed on a boundary between the plurality of sub pixels SP and partially cover the first connection electrode CE1 and the second connection electrode CE2. The black matrix BM may be disposed to be spaced apart from the transmissive area TA. The black matrix BM may be made of an opaque material, for example, black resin to reduce a color mixture between the plurality of sub pixels SP. However, the present disclosure is not limited thereto.

A protective layer 116 is disposed on the first connection electrode CE1, the second connection electrode CE2, and the black matrix BM. The protective layer 116 is a layer for protecting components disposed below the protective layer 116. The protective layer 116 may be configured as a single layer or multilayer made of organic material such as benzocyclobutene, light transmissive epoxy, a photoresist, an acrylic-based organic material, or an inorganic material such as silicon oxide (SiOx) or silicon nitride (SiNx), for example. However, the present disclosure is not limited thereto.

Meanwhile, an illumination inspection process for detecting a defective sub pixel SP may be performed during a process of manufacturing the display device 100. For example, a defective sub pixel SP, which does not emit light, may be detected by operating the plurality of light-emitting elements 120 in the state in which the plurality of light-emitting elements 120, the first connection electrode CE1, and the second connection electrode CE2 are formed. For example, the defective sub pixel SP may be caused by a defect of the pixel circuit, a transfer defect of the light-emitting element 120, or foreign substances. Therefore, in the display device 100 according to embodiments of the present disclosure, a process of repairing the defective sub pixel SP may be performed, thereby improving the quality of the display device 100.

For example, when a defect occurs on any one of the plurality of sub pixels SP, the repair line WRL may be used to connect the light-emitting element 120 of the defective sub pixel SP to a pixel circuit of a normal sub pixel SP, such that the light-emitting element 120 of the defective sub pixel SP may be operated by the pixel circuit of the normal sub pixel SP. Therefore, the plurality of repair lines WRL for repair is disposed in the display device 100.

With reference to FIGS. 3 to 5B together, the plurality of repair lines WRL is disposed on the third planarization layer 115c. When a defective sub pixel SP occurs, the plurality of repair lines WRL are lines for electrically connecting the light-emitting element 120 of the defective sub pixel SP to the driving transistor DT of the normal adjacent sub pixel SP. The light-emitting element 120 of the defective sub pixel SP may be operated by being connected to the driving transistor DT of the normal sub pixel SP by the repair line WRL. Therefore, even though a defect occurs on the circuit of the sub pixel SP, it is possible to eliminate a dark spot defect by operating the light-emitting element 120 by connecting the light-emitting element 120 to the circuit of another sub pixel SP by using the repair line WRL.

The plurality of repair lines WRL may be disposed between the same types of sub pixels SP. For example, the repair lines WRL may be disposed between the pair of first sub pixels SP1a and SP1b, between the pair of second sub pixels SP2a and SP2b, and between the pair of third sub pixels SP3a and SP3b. The plurality of repair lines WRL may be disposed between the first A-type sub pixel SP1a and the first B-type sub pixel SP1b, between the second A-type sub pixel SP2a and the second B-type sub pixel SP2b, and between the third A-type sub pixel SP3a and the third B-type sub pixel SP3b.

The repair line WRL may be connected to the first connection electrode CE1 of one of the pair of sub pixels SP and disposed to be spaced apart from the first connection electrode CE1 of the other of the pair of sub pixels SP. That is, the repair line WRL may be disposed between the first A-type sub pixel SP1a and the first B-type sub pixel SP1b and connected directly to the first connection electrode CE1 of the first A-type sub pixel SP1a. The repair line WRL may be disposed between the second A-type sub pixel SP2a and the second B-type sub pixel SP2b and connected directly to the first connection electrode CE1 of the second A-type sub pixel SP2a. The repair line WRL may be disposed between the third A-type sub pixel SP3a and the third B-type sub pixel SP3b and connected directly to the first connection electrode CE1 of the third A-type sub pixel SP3a. Further, the repair line WRL may be disposed to be spaced apart from the first connection electrode CE1 of each of the first B-type sub pixel SP1b, the second B-type sub pixel SP2b, and the third B-type sub pixel SP3b.

The repair line WRL may be disposed between the A-type sub pixel SPa and the B-type sub pixel SPb disposed in the different pixel areas UPA. The repair line WRL may extend from the A-type sub pixel SPa within a shortest straight distance toward the B-type sub pixel SPb disposed in the pixel area UPA in the adjacent column. The repair line WRL may extend within a shortest straight distance toward the B-type sub pixel SPb disposed to be closest to the A-type sub pixel SPa, and the repair line WRL may be disposed to traverse the transmissive area TA. Because the repair line WRL is made of a transparent conductive material, like the first connection electrode CE1, it is possible to minimize the decrease in transmittance rate even though the repair line WRL is disposed to traverse the transmissive area TA.

For example, some of the plurality of repair lines WRL may each be disposed between the A-type sub pixel SPa of the pixel area UPA in the n-th column and the B-type sub pixel SPb of the pixel area UPA in the (n+1)th column. Some of the remaining repair lines WRL may each be disposed between the A-type sub pixel SPa of the pixel area UPA in the n-th column and the B-type sub pixel SPb of the pixel area UPA in the (n−1)th column. For example, the repair line WRL may be disposed between the first sub pixels SP1a and SP1b in the (n+1)th column and one of the pair of first sub pixels SP1a and SP1b disposed in the pixel area UPA in the n-th column. Further, the repair line WRL may be disposed between the first sub pixels SP1a and SP1b in the (n−1)th column and the other of the pair of first sub pixels SP1a and SP1b disposed in the pixel area UPA in n-th column. Therefore, the pair of sub pixels SP included in one pixel area UPA may be respectively connected to the sub pixels SP in the different pixel areas UPA during the repair process.

Next, the A-type sub pixel SPa may be connected to the repair line WRL, and the B-type sub pixel SPb may be disposed adjacent to the repair line WRL and separated from the repair line WRL without being connected to the repair line WRL. The first connection electrode CE1 disposed in the A-type sub pixel SPa may be integrated with and electrically connected to the repair line WRL. The first connection electrode CE1 disposed in the B-type sub pixel SPb may be disposed to be spaced apart from the repair line WRL. Therefore, one end of each of the plurality of repair lines WRL may be connected to the first connection electrode CE1 of the A-type sub pixel SPa, and the other end of the repair line WRL may be disposed to be spaced apart from the first connection electrode CE1 of the B-type sub pixel SPb.

Further, in the B-type sub pixel SPb, the repair line WRL may be disposed in the welding area WA. In the welding area WA, the repair line WRL and the first reflective electrode RE1 of the B-type sub pixel SPb may be disposed to overlap each other. The repair line WRL and the first reflective electrode RE1 of the B-type sub pixel SPb are disposed in the welding area WA and overlap. In the welding area WA that is not subjected to the welding process, the repair line WRL and the first reflective electrode RE1 may be disposed to be spaced apart from each other with the third planarization layer 115c, the second planarization layer 115b, the bonding layer AD, and the third passivation layer 114c interposed therebetween. In contrast, in the welding area WA that has been subjected to the welding process, the repair line WRL and the first reflective electrode RE1 may be connected to each other as the third planarization layer 115c, the second planarization layer 115b, the bonding layer AD, and the third passivation layer 114c are partially removed.

Hereinafter, the description will be made on the assumption that a defect occurs on the A-type sub pixel SPa, a dark-spot process is performed on the A-type sub pixel SPa, and the repair line WRL is connected to the B-type sub pixel SPb to repair the A-type sub pixel SP.

First, with reference to FIG. 5A, when a defect occurs on any one of the plurality of sub pixels SP, the dark-spot process of separating the pixel circuit of the defective sub pixel SP and the light-emitting element 120 may be performed. If the pixel circuit of the defective sub pixel SP and the light-emitting element 120 are not electrically separated, a bright spot defect or the like may occur because the light-emitting elements 120 of some of the defective sub pixels SP abnormally operate. For example, the light-emitting element 120 of the defective sub pixel SP continuously emits light regardless of images, which may cause a defect in which a bright spot is recognized. Therefore, the pixel circuit of the defective sub pixel SP and the light-emitting element 120 may be separated so that the drive current is not supplied from the pixel circuit of the defective sub pixel SP to the light-emitting element 120.

For example, a drive current transmission route between the light-emitting element 120 and the pixel circuit of the defective sub pixel SP may be eliminated by destroying the connection portion between the light-emitting element 120 and the driving source electrode DSE of the driving transistor DT. For example, the light-emitting element 120 and the driving transistor DT may be electrically connected to each other through the first reflective electrode RE1 and the first connection electrode CE1. Further, the connection portion between the pixel circuit and the light-emitting element 120 may be destroyed by irradiating the connection portion between the first reflective electrode RE1 and the driving transistor DT with laser beams. For example, the portion where the first reflective electrode RE1 and the driving transistor DT are electrically connected may be destroyed by irradiating the first contact hole CH1, through which the first reflective electrode RE1 and the auxiliary electrode AE are connected, with laser beams.

For example, with reference to FIG. 5B, in case that a defect occurs on the circuit of the A-type sub pixel SPa, the first contact hole CH1 may be destroyed by irradiating the first contact hole CH1 of the A-type sub pixel SPa with laser beams.

As described above, the first reflective electrode RE1 may include a portion, which overlaps the first connection electrode CE1, and a portion that does not overlap the first connection electrode CE1. The first reflective electrode RE1 and the driving transistor DT may be electrically connected through the first contact hole CH1 formed to correspond to the portion that does not overlap the first connection electrode CE1. The first reflective electrode RE1 is electrically connected to the auxiliary electrode AE through the first contact hole CH1, and the auxiliary electrode AE is electrically connected to the driving source electrode DSE of the driving transistor DT through the contact holes of the first passivation layer 114a and the second interlayer insulation layer 113b. The first contact hole CH1, which connects the first reflective electrode RE1 and the auxiliary electrode AE, may overlap the first reflective electrode RE1 without overlapping the first connection electrode CE1.

Further, the first contact hole CH1 may be irradiated with laser beams, such that the connection portion of the first contact hole CH1, which connects the first reflective electrode RE1 and the auxiliary electrode AE, may be destroyed. Therefore, when the first reflective electrode RE1 and the auxiliary electrode AE are electrically separated as the first contact hole CH1 is destroyed, the first reflective electrode RE1 and the driving transistor DT may also be electrically separated. Therefore, as the portion where the first reflective electrode RE1 and the driving source electrode DSE are electrically connected is damaged, the driving transistor DT and the light-emitting element 120 may be separated, and a bright spot defect may be suppressed.

The dark-spot process may be performed by irradiating the first contact hole CH1, which does not overlap the first connection electrode CE1, with laser beams, which may suppress damage to the first connection electrode CE1. In particular, in case that a defect occurs on the pixel circuit of the A-type sub pixel SPa and the dark-spot process is performed on the A-type sub pixel SPa by irradiating the first connection electrode CE1 with laser beams, the first connection electrode CE1 and the repair line WRL may be separated. Therefore, the light-emitting element 120 of the A-type sub pixel SPa cannot be electrically connected to the driving transistor DT of the B-type sub pixel SPb later, and the A-type sub pixel SPa cannot be repaired. Therefore, the first contact hole CH1, which is to be subjected to the dark-spot process, is formed so as not to overlap the first connection electrode CE1, which may minimize damage to the first connection electrode CE1 and the repair line WRL.

Next, with reference to FIG. 6, the repair line WRL and the driving transistor DT of the B-type sub pixel SPb may be electrically connected by irradiating the repair line WRL, which extends from the A-type sub pixel SPa that has been subjected to the dark-spot process, with laser beams.

First, an end of the repair line WRL, which extends from the A-type sub pixel SPa, may be disposed in the welding area WA of the B-type sub pixel SPb in the adjacent pixel area UPA. For example, with reference to FIG. 5B, before the repair process is performed, the repair line WRL in the welding area WA of the B-type sub pixel SPb is disposed to overlap the first reflective electrode RE1 and spaced apart from the first reflective electrode RE1. That is, before the repair process is performed, the repair line WRL and the first reflective electrode RE1 may be disposed to be spaced apart from each other with the third planarization layer 115c, the second planarization layer 115b, the bonding layer AD, and the third passivation layer 114c interposed therebetween.

Further, with reference to FIG. 6, the welding process of connecting the repair line WRL and the first reflective electrode RE1 by irradiating the welding area WA with laser beams may be performed. In case that the welding area WA is irradiated with laser beams, the third planarization layer 115c, the second planarization layer 115b, the bonding layer AD, and the third passivation layer 114c, which correspond to the welding area WA, may be destroyed, such that the repair line WRL and the first reflective electrode RE1 may be connected to each other. The insulation layers between the repair line WRL and the first reflective electrode RE1 may be destroyed in an atypical shape, such that the first reflective electrode RE1 and the repair line WRL may be electrically connected to each other.

Therefore, the first connection electrode CE1 of the B-type sub pixel SPb may be electrically connected to the repair line WRL through the first reflective electrode RE1. That is, the first connection electrode CE1 may be connected indirectly to the repair line WRL through the first reflective electrode RE1.

Therefore, the driving transistor DT of the B-type sub pixel SPb may be electrically connected to the first connection electrode CE1 of the light-emitting element 120 of the A-type sub pixel SPa through the auxiliary electrode AE, the first reflective electrode RE1, and the repair line WRL. The driving transistor DT of the B-type sub pixel SPb may be electrically connected to both the first connection electrode CE1 of the A-type sub pixel SPa and the first connection electrode CE1 of the B-type sub pixel SPb. Therefore, the light-emitting element 120 of the A-type sub pixel SPa and the light-emitting element 120 of the B-type sub pixel SPb may be connected in parallel to the driving transistor DT of the B-type sub pixel SPb and operate together.

Therefore, in the display device 100 according to embodiments of the present disclosure, the A-type sub pixel SPa and the B-type sub pixel SPb may be alternately disposed in the same row, such that the plurality of repair lines WRL may be formed as a straight line extending within a shortest distance. The repair line WRL, which connects the A-type sub pixel SPa and the B-type sub pixel SPb, may extend straight in the row direction. The A-type sub pixel SPa and the B-type sub pixel SPb may be disposed on the same line, such that the repair line WRL may extend straight within a shortest straight distance. In addition, the pair of light-emitting elements 120, which is disposed with the repair line WRL interposed therebetween, may be disposed to be vertically symmetric, such that the plurality of repair lines WRL may be formed within the shortest straight length. The repair line WRL may normally supply the drive current to the light-emitting element 120 of the defective sub pixel SP by electrically connecting the first electrodes 124 of the light-emitting elements 120. In this case, the pair of light-emitting elements 120 is disposed to be vertically symmetric, such that the two light-emitting elements 120 may be disposed so that the first electrodes 124 face each other. Therefore, a distance between the first electrodes 124 of the pair of light-emitting elements 120 may be minimized, and the repair line WRL may be formed within a shortest straight length. Therefore, the structure of the repair line WRL may be simplified, the length of the repair line WRL may be reduced, and the resistance of the repair line WRL may be improved. The reduction in length of the repair line WRL may reduce the line resistance and reduce the power consumption, such that the display device 100 may operate with low power consumption.

In the display device 100 according to embodiments of the present disclosure, all the plurality of repair lines WRL may be formed to be parallel, such that the plurality of repair lines WRL may not interfere with the other repair lines WRL. The plurality of repair lines WRL may each connect the A-type sub pixel SPa and the B-type sub pixel SPb disposed in the same row and adjacent to each other. The plurality of repair lines WRL may extend straight in the row direction and disposed in parallel with one another. Therefore, it is possible to suppress the interference between the repair lines WRL that occurs in case that the repair line WRL connected to the sub pixel SP in a particular row extends toward the sub pixel SP in another row. In addition, because the interference between the plurality of repair lines WRL is suppressed, the plurality of repair lines WRL does not need to be formed as a plurality of conductive layers, and the plurality of repair lines WRL may be formed to have a single layer structure made of a transparent conductive material. Therefore, the structures of the plurality of repair lines WRL may be simplified. In addition, the plurality of repair lines WRL may be formed as a single layer made of a transparent conductive material, which may minimize a decrease in transmittance rate caused by the plurality of repair lines WRL.

In the display device 100 according to embodiments of the present disclosure, the plurality of red light-emitting elements 120R, the plurality of green light-emitting elements 120G, and the plurality of blue light-emitting elements 120B may be disposed at uniform intervals, which may improve the image quality. Because the plurality of repair lines WRL is disposed straight in the row direction, the plurality of red light-emitting elements 120R may be disposed in the same row, the plurality of green light-emitting elements 120G may be disposed in the same row, and the plurality of blue light-emitting elements 120B may be disposed in the same row. For example, the red light-emitting element 120R may be disposed only in an n-the row, the green light-emitting element 120G may be disposed only in an (n+1) the row, and the blue light-emitting element 120B may be disposed only in an (n+2) the row. In this case, the design of the repair line WRL is not limited thereto. The arrangement order of the plurality of red light-emitting elements 120R, the plurality of green light-emitting elements 120G, and the plurality of blue light-emitting elements 120B in the column direction may be freely configured. For example, because the repair line WRL, which connects the plurality of red light-emitting elements 120R, the plurality of green light-emitting elements 120G, and the plurality of blue light-emitting elements 120B, connects only the light-emitting elements 120 disposed in the same row, the repair line WRL may be formed regardless of the arrangement order of the red light-emitting element 120R, the green light-emitting element 120G, and the blue light-emitting element 120B in the column direction. If the repair line WRL is configured to connect the light-emitting elements 120 disposed in different rows, the arrangement order of the red light-emitting element 120R, the green light-emitting element 120G, and the blue light-emitting element 120B may be restricted in consideration of the interference between the repair lines WRL that connect the light-emitting elements 120. Therefore, the arrangement order of the red light-emitting element 120R, the green light-emitting element 120G, and the blue light-emitting element 120B is not restricted to a particular order in accordance with the repair line WRL. Therefore, the plurality of red light-emitting elements 120R, the plurality of green light-emitting elements 120G, and the plurality of blue light-emitting elements 120B may be sequentially and alternately disposed in the column direction, such that the interval between the red light-emitting elements 120R, the interval between the green light-emitting elements 120G, and the interval between the blue light-emitting elements 120B may be uniformly implemented.

The example embodiments of the present disclosure can also be described as follows:

According to an aspect of the present disclosure, a display device includes a substrate configured to define a plurality of pixel areas disposed to be spaced apart from one another, and a plurality of transmissive areas disposed between the plurality of pixel areas, a plurality of pixels disposed in the plurality of pixel areas and each including a plurality of sub pixels, light-emitting elements respectively disposed in the plurality of sub pixels and each including a first electrode, and a repair line disposed between a pair of adjacent sub pixels among the plurality of sub pixels, the light-emitting elements of the pair of sub pixels are disposed so that the first electrodes are directed toward the repair line.

The display device may further include first connection electrodes respectively disposed in the plurality of sub pixels and each electrically connected to the first electrode of the light-emitting element, the plurality of sub pixels may include an A-type sub pixel in which the repair line and the first connection electrode are connected, and a B-type sub pixel in which the repair line and the first connection electrode are spaced apart from each other.

The pair of sub pixels, which is disposed with the repair line interposed therebetween, may be configured as the A-type sub pixel and the B-type sub pixel, and the light-emitting element of the A-type sub pixel and the light-emitting element of the B-type sub pixel may be disposed to be symmetric with respect to the repair line.

The A-type sub pixel and the B-type sub pixel may be alternately disposed in the same row.

The repair line may be disposed between the A-type sub pixel and the B-type sub pixel disposed in the same row and adjacent to each other.

The plurality of transmissive areas may be formed between the A-type sub pixel and the B-type sub pixel, the repair line may be disposed to traverse the plurality of transmissive areas, and the repair line may be made of a transparent conductive material.

The plurality of pixels each may include both one or more A-type sub pixels and one or more B-type sub pixels.

The display device may further include a scan line extending in a row direction and disposed to traverse the plurality of pixel areas, in some of the plurality of pixel areas, the A-type sub pixel may be disposed in an area at one side of the scan line, and the B-type sub pixel may be disposed in an area at the other side of the scan line.

In the remaining pixel areas among the plurality of pixel areas, the B-type sub pixel may be disposed in an area at one side of the scan line, and the A-type sub pixel may be disposed in an area at the other side of the scan line, and some of the pixel areas and the remaining pixel areas may be disposed in different columns.

The display device may further include a driving transistor provided on the substrate and disposed in each of the plurality of sub pixels, one or more insulation layers disposed on the driving transistor, a first reflective electrode disposed between the one or more insulation layers and the light-emitting element and electrically connected to the driving transistor through a first contact hole of the one or more insulation layers, and a planarization layer disposed on the first reflective electrode and configured to cover the light-emitting element, the first connection electrode may be disposed on the planarization layer and the light-emitting element and electrically connected to the first electrode and the first reflective electrode.

The repair line may be disposed on the same layer as the first connection electrode, the repair line in the A-type sub pixel may be integrated with the first connection electrode, and the repair line in the B-type sub pixel may be spaced apart from the first connection electrode and may overlap a part of the first reflective electrode.

The first reflective electrode and the repair line may be connected to each other in some of the B-type sub pixels among the plurality of sub pixels, and the first reflective electrode and the repair line may be spaced apart from each other with the planarization layer interposed therebetween in some of the remaining B-type sub pixels among the plurality of sub pixels.

The first electrode of the light-emitting element in some of the B-type sub pixels may be electrically connected to the first connection electrode, the first reflective electrode, and the driving transistor in the A-type sub pixel in an adjacent column through the first connection electrode, the first reflective electrode, and the repair line.

In the A-type sub pixel and the B-type sub pixel, the repair lines may not overlap the first contact holes.

The display device may further include a plurality of data lines extending in a column direction on the substrate, the plurality of pixel areas may overlap an area in which the plurality of data lines is disposed.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

The various embodiments described above can be combined to provide further embodiments. Aspects of embodiments can be modified, if necessary to employ concepts of the various embodiments to provide yet further embodiments.

These and other changes can be made to embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a plurality of pixel areas spaced apart from one another, and a plurality of transmissive areas disposed between the plurality of pixel areas;
a plurality of pixels disposed in the plurality of pixel areas and each including a plurality of sub pixels;
light-emitting elements respectively disposed in the plurality of sub pixels and each including a first electrode; and
a repair line disposed between a pair of adjacent sub pixels among the plurality of sub pixels,
wherein the light-emitting elements of the pair of sub pixels are disposed so that the first electrodes are directed toward the repair line.

2. The display device of claim 1, further comprising:
first connection electrodes respectively disposed in the plurality of sub pixels and each electrically connected to the first electrode of the light-emitting element,
wherein the plurality of sub pixels comprises:
an A-type sub pixel in which the repair line and the first connection electrode are connected; and
a B-type sub pixel in which the repair line and the first connection electrode are spaced apart from each other.

3. The display device of claim 2, wherein the pair of sub pixels, which is disposed with the repair line interposed therebetween, include an A-type sub pixel and a B-type sub pixel, and
wherein the light-emitting element of the A-type sub pixel and the light-emitting element of the B-type sub pixel are disposed to be symmetric with respect to the repair line.

4. The display device of claim 2, wherein the A-type sub pixel and the B-type sub pixel are alternately disposed in a same row.

5. The display device of claim 4, wherein the repair line is disposed between the A-type sub pixel and the B-type sub pixel disposed in the same row and adjacent to each other.

6. The display device of claim 5, wherein the plurality of transmissive areas is each formed between the A-type sub pixel and the B-type sub pixel, the repair line traverses one or more transmissive areas of the plurality of transmissive areas, and the repair line is made of a transparent conductive material.

7. The display device of claim 2, wherein the plurality of pixels each includes one or more A-type sub pixels and one or more B-type sub pixels.

8. The display device of claim 7, further comprising:
a scan line extending in a row direction and traversing one or more pixel areas of the plurality of pixel areas,
wherein in first pixel areas of the plurality of pixel areas, an A-type sub pixel is disposed in an area at a first side of the scan line, and a B-type sub pixel is disposed in an area at a second side of the scan line.

9. The display device of claim 8, wherein in second pixel areas among the plurality of pixel areas, a B-type sub pixel is disposed in an area at the first side of the scan line, and an A-type sub pixel is disposed in an area at the second side of the scan line, and
wherein the first pixel areas and the second pixel areas are disposed in different columns.

10. The display device of claim 2, further comprising:
a driving transistor provided on the substrate and disposed in each of the plurality of sub pixels;
one or more insulation layers disposed on the driving transistor;
a first reflective electrode disposed between the one or more insulation layers and the light-emitting element and electrically connected to the driving transistor through a first contact hole in the one or more insulation layers; and
a planarization layer disposed on the first reflective electrode and covering the light-emitting element,
wherein the first connection electrode is disposed on the planarization layer and the light-emitting element and electrically connected to the first electrode and the first reflective electrode.

11. The display device of claim 10, wherein the repair line is disposed on a same layer as the first connection electrode, the repair line in the A-type sub pixel is integrated with the first connection electrode, and the repair line in the B-type sub pixel is spaced apart from the first connection electrode and overlaps a part of the first reflective electrode.

12. The display device of claim 11, wherein the first reflective electrode and the repair line are connected to each other in first B-type sub pixels of the B-type sub pixels among the plurality of sub pixels, and
wherein the first reflective electrode and the repair line are spaced apart from each other with the planarization layer interposed therebetween in second B-type sub pixels of the B-type sub pixels among the plurality of sub pixels.

13. The display device of claim 12, wherein the first electrode of the light-emitting element in a B-type sub pixels is electrically connected to the first connection electrode, the first reflective electrode, and the driving transistor in an A-type sub pixel in an adjacent column through the first connection electrode, the first reflective electrode, and the repair line.

14. The display device of claim 10, wherein in the A-type sub pixel and the B-type sub pixel, the repair line does not overlap the first contact holes.

15. The display device of claim 1, further comprising:
a plurality of data lines extending in a column direction on the substrate,
wherein the plurality of pixel areas overlaps an area in which the plurality of data lines is disposed.

16. A display device comprising:
a substrate including a plurality of pixel areas spaced apart from one another, and a plurality of transmissive areas disposed between the plurality of pixel areas;
a plurality of pixels disposed in the plurality of pixel areas and each including a plurality of sub pixels, a pixel area of the plurality of pixel areas including a first subpixel and a second subpixel, the first subpixel and the second subpixel configured to emit light of a same color, each of the first subpixel and the second subpixel including a first electrode; and
a repair line disposed adjacent to the pixel area, the first electrode of the first subpixel connected to the repair line, and the first electrode of the second subpixel not connected to the repair line.

17. The display device of claim 16, wherein the repair line extends in a transmissive area.

18. The display device of claim 16, comprising a scan line that traverses the pixel area, the first subpixel positioned at a first side of the scan line, and the second subpixel positioned at a second side of the scan line opposite to the first side.

19. The display device of claim 16, wherein the repair line is connected to the first electrode of the first subpixel via a connection electrode that is on a same level as the repair line.

20. A structure, comprising:
a first semiconductor layer;
a first electrode on the first semiconductor layer;
a light-emitting layer on the first semiconductor layer and lateral to the first electrode;
a second semiconductor layer on the light-emitting layer and not on the first electrode;
a second electrode on the second semiconductor layer;
a first connection electrode in contact with the first electrode; and
a second connection electrode in contact with the second electrode, the second connection electrode isolated from the first connection electrode.
